(19) United States
(12) Patent Application Publication
(10) Pub. No.: US 2018/0158788 A1
(43) Pub. Date: Jun. 7, 2018

(54) MIXED STRUCTURE METHOD OF LAYOUT OF DIFFERENT SIZE ELEMENTS TO OPTIMIZE THE AREA USAGE ON A WAFER

(71) Applicant: AVERY DENNISON RETAIL INFORMATION SERVICES, LLC, Mentor, OH (US)

(72) Inventor: Ian J. FORSTER, Chelmsford (GB)

(21) Appl. No.: 15/828,733

(22) Filed: Dec. 1, 2017

Related U.S. Application Data
(60) Provisional application No. 62/428,873, filed on Dec. 1, 2016.

(51) Int. Cl. H01L 23/66; H04B 1/40

(52) U.S. Cl. CPC H01L 23/66; H04B 1/40; H01L 2924/1421; H01L 2924/1434; H01L 2223/6677

(57) ABSTRACT

A semiconductor wafer device that comprises a round wafer with a large surface area and a low cost per unit area is disclosed. The semiconductor wafer device comprises mixed size elements, such that a plurality of large devices are manufactured on the wafer, as well as a plurality of small devices are manufactured on the wafer. The small devices act as fill in elements for the wafer, as the plurality of large devices do not efficiently fill in the wafer. Typically, the large devices comprise strap or interposer devices and the small devices comprise chip devices. The chip devices attach to small RFID antennas and the interposer devices attach to larger structures, such as high frequency tags where the strap/interposer can act as a bridge from the center of an antenna coil to the outside.

### CROSS REFERENCE TO RELATED APPLICATION(S)

The present application claims priority to and the benefit of U.S. Provisional Utility Patent Application No. 62/428,873 filed Dec. 1, 2016, which is incorporated herein by reference in its entirety.

### BACKGROUND

The present invention relates generally to a semiconductor wafer device. Specifically, the semiconductor wafer device comprises a round wafer with a large surface area and a low cost per unit area. The semiconductor wafer device comprises mixed size elements, such that a plurality of large devices are manufactured on the wafer, as well as a plurality of small devices are manufactured on the wafer.

In the manufacture of semiconductor devices, a plurality of integrated circuits are simultaneously prepared in a semiconductor wafer through the use of conventional photolithographic techniques. It is also convenient to provide a plurality of secondary devices such as contact pads, test monitor devices, devices for measurement and alignment, etc. on the planar surface adjacent the outer perimeter of each integrated circuit or other semiconductor device.

Furthermore, based on the lower cost per unit area of the semiconductor wafer device, it is possible to create larger devices suitable for acting as strap interposers. However, the larger size of semiconductor wafer typically means that a user cannot efficiently use all of the area of a semiconductor wafer.

Accordingly, the present invention discloses a semiconductor wafer device comprising mixed size elements, such that small size devices can be utilized on the wafer device to act as fill in elements for the wafer, as the plurality of large size devices do not efficiently fill in the wafer.

### SUMMARY

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The subject matter disclosed and claimed herein, in one aspect thereof, comprises a semiconductor wafer device that comprises a round wafer with a large surface area and a low cost per unit area. The semiconductor wafer device comprises mixed size elements, such that a plurality of large devices are manufactured on the wafer, as well as a plurality of small devices are manufactured on the wafer. The small devices act as fill in elements for the wafer, as the plurality of large devices do not efficiently fill in the wafer. Typically, the large devices are greater than 4 mm² and the small devices are less than 4 mm². Further, the large devices typically comprise strap or interposer devices and the small devices typically comprise chip devices. The chip devices attach to small RFID antennas and the interposer devices attach to larger structures, such as high frequency tags where the strap/interposer can act as a bridge from the center of an antenna coil to the outside.

In another embodiment, the semiconductor wafer device with mixed size elements further comprises a 3-D stack of devices. The 3-D stack of devices is created by picking up components and placing them on top of each other, increasing functionality in a given area. Typically, the smaller part or top component is a digital processor, and the larger part or bottom component is a sensor, photovoltaic or other device such as a display. In one embodiment, when there is insufficient area to have both a coil and a chip in the same area separately, the larger part or bottom component is a high density coil. Thus, the process of creating a 3-D stack of devices makes use of the thinness and flexibility of the chip devices to create an area efficient semiconductor wafer device.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE DRAWINGS

FIG. 1 illustrates a top perspective view of the semiconductor wafer device with mixed size elements in accordance with the disclosed architecture.

FIG. 2 illustrates a top perspective view of the semiconductor wafer device with laser cut, mixed size elements in accordance with the disclosed architecture.

FIG. 3A illustrates a top perspective view of the semiconductor wafer device with a 3-D stack of mixed size elements in accordance with the disclosed architecture.

FIG. 3B illustrates a side perspective view of the semiconductor wafer device with a 3-D stack of mixed size elements in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof.

New processes for creating chips can make relatively large flexible parts that can be used as straps which can be used on antennas but also as bridges for high frequency antennas. These larger devices do not efficiently fill the wafer area, so in this invention a smaller part is also created on the wafer. Thus, the present invention discloses a semiconductor wafer device that comprises a round wafer with a large surface area and a low cost per unit area. The semiconductor wafer device comprises mixed size elements, such that a plurality of large devices are manufactured on the wafer, as well as a plurality of small devices are manufactured on the wafer. The small devices act as fill in elements for the wafer, as the plurality of large devices do not efficiently fill in the wafer. Typically, the large devices comprise strap or interposer devices and the small devices comprise chip devices. The chip devices attach to small RFID antennas and the interposer devices attach to larger structures, such as high frequency tags where the strap/interposer can act as a bridge from the center of an antenna coil to the outside.

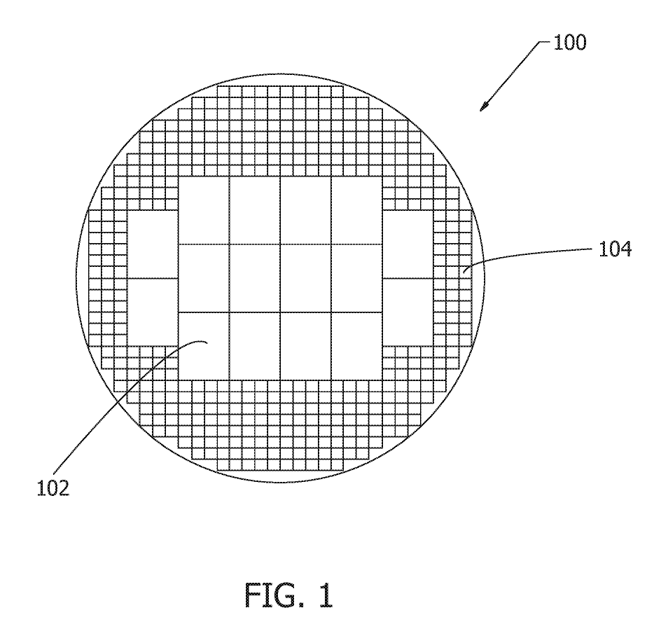

Referring initially to the drawings, FIG. 1 illustrates a first exemplary embodiment of a round semiconductor wafer device 100 with mixed size elements. Specifically, the semiconductor wafer device 100 can be any suitable size, shape, and configuration as is known in the art without affecting the overall concept of the invention. One of ordinary skill in the art will appreciate that the shape and size of the semiconductor wafer device 100 as shown in FIG. 1 is for illustrative purposes only and many other shapes and sizes of the semiconductor wafer device 100 are well within the scope of the present disclosure. Further, although dimensions of the semiconductor wafer device 100 (i.e., length, width, and height) are important design parameters for good performance, the semiconductor wafer device 100 may be any shape or size that ensures optimal performance and sensitivity during use.

Typically, the semiconductor wafer device 100 is inexpensive to manufacture, as such it has a low cost per unit area. Given the lower cost per unit area of the semiconductor wafer device 100, it is possible to create larger devices suitable for acting as strap interposers, and other suitable devices as is known in the art. However, the larger size of wafer device 100 typically means a user cannot efficiently use all of the area of the wafer.

One way to efficiently use more of the area of the wafer, is to utilize mixed size elements on the wafer. Thus, a round wafer is shown in FIG. 1 with both large 102 and small 104 devices manufactured on the same sheet. The small devices 104 are typically components that are less than 4 mm², or any other suitable size as is known in the art. The large devices 102 are typically components that are greater than 4 mm², or any other suitable size as is known in the art. Further, the smaller devices 104, are analogous to chips and other suitable devices as is known in the art, and the large devices 102 are analogous to straps/interposers and other suitable devices as is known in the art. The chips (small devices 104) are ideal for attachment to small RFID antennas, and other suitable devices. The straps/interposers (large devices 102) are ideal for attachment to larger structures, including high frequency (HF) tags where the strap can act as a bridge from the center of an antenna coil to the outside, and other suitable devices as is known in the art.

Typically, utilizing mixed sized elements on the wafer device 100 is only applicable to semiconductor wafer devices 100 which have a low cost per unit area and that make a flexible chip. For example, a greater than 4 mm² device used as a strap/bridge in silicon would be comparatively expensive and also fragile. In contrast, the round wafer device 100 with a low cost per unit area shown in FIG. 1 discloses a plurality of large area straps/interposers 102 that do not efficiently fill in the wafer device 100. Further, as shown, the area that would otherwise not be used is filled in by smaller devices 104, such as chips.

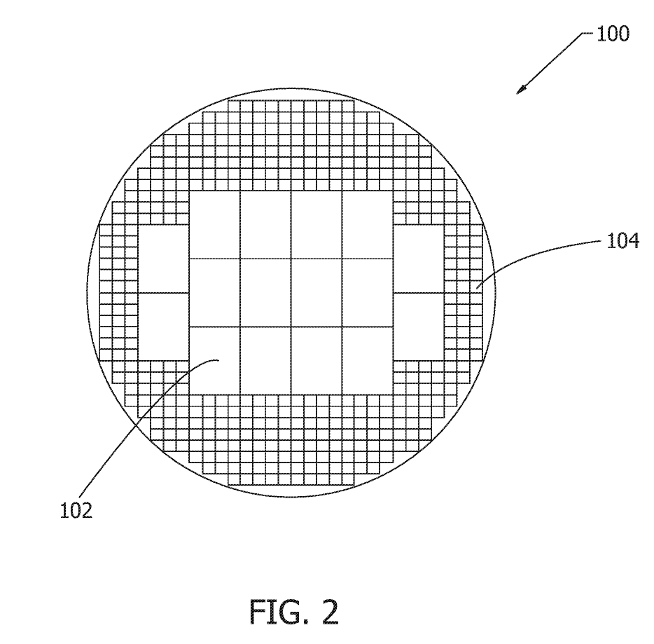

Additionally, the large devices (strap devices) 102 and small devices (chip devices) 104 are typically used in different processes, but could be used in the same process as well. If used in different processes, laser cutting and ejection is done in two steps to separate the device stream. For example, as shown in FIG. 2, the strap devices 102 and chip devices 104 are released or ejected from the wafer device 100 at different times, as they are likely to be used in different processes. Typically, the strap devices 102 are laser cut and ejected first and the chip devices 104 are laser cut and ejected second, or the chip devices 104 can be laser cut and ejected first and the strap devices 102 laser cut and ejected second. Thus, the laser cutting and ejection of the devices 102 and 104 is performed in two steps to separate the device stream, but does not have to be and the laser cutting and ejection of the devices 102 and 104 can be performed at the same time as well.

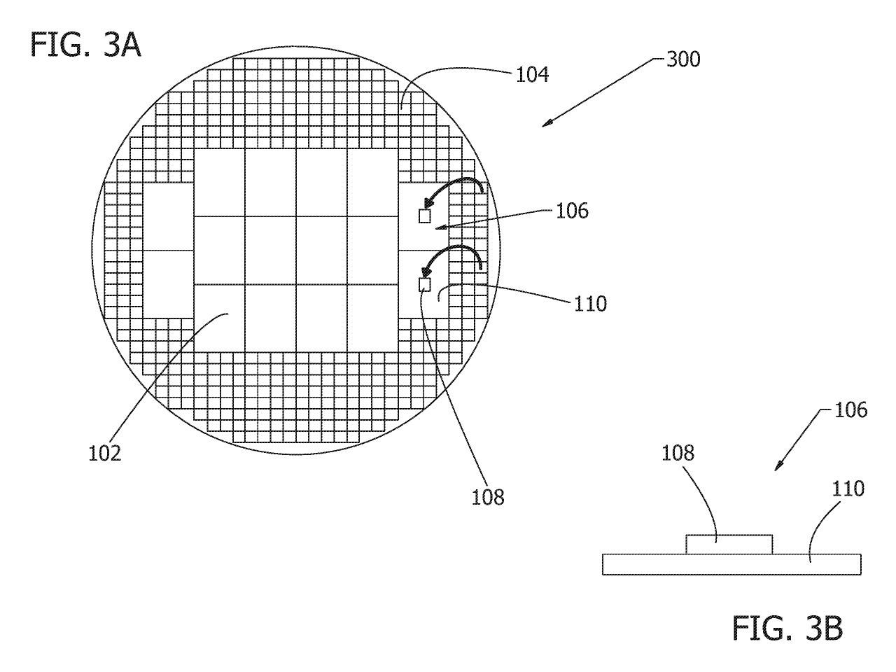

FIGS. 3A-B illustrate another exemplary embodiment of a semiconductor wafer device 300 with mixed size elements, however this wafer device 300 also comprises a 3-D stack of devices 106. Typically, the 3-D stack of devices 106 is created by picking up parts or components and placing them on top of each other (one on top of the other), increasing functionality in a given area. For example, the smaller part (or top component 108) maybe a chip or a digital processor or other suitable device as is known in the art, and the larger part (or bottom component 110) can be a sensor, photovoltaic or other device such as a display or other suitable large area device as is known in the art. In one embodiment, if there is insufficient area to have both the antenna coil and the chip in the same area separately, then the larger device (bottom component 108) would typically be a high density antenna coil. Furthermore, although the chips (top components 108) are shown as being different sizes, the process of creating the 3-D stack of parts 106, would make use of the thinness and flexibility of the chips 108 to create an area efficient device 300.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A semiconductor wafer device, comprising:
a wafer with a large surface area;
a plurality of large devices manufactured on the wafer; and
a plurality of small devices manufactured on the wafer; and
wherein the small devices act as fill in elements for the wafer, as the plurality of large devices do not efficiently fill in the wafer.

2. The semiconductor wafer device of claim 1, wherein the wafer is round in shape.

3. The semiconductor wafer device of claim 1, wherein the wafer has a low cost per unit area.

4. The semiconductor wafer device of claim 1, wherein the wafer functions as a strap interposer.

5. The semiconductor wafer device of claim 1, wherein the large devices comprise strap or interposer devices.

6. The semiconductor wafer device of claim 5, wherein the large devices are greater than 4 mm².

7. The semiconductor wafer device of claim 6, wherein the strap or interposer devices attach to high frequency tags.

8. The semiconductor wafer device of claim 7, wherein the strap or interposer devices act as a bridge from a center to an outside of an antenna coil.

9. The semiconductor wafer device of claim 1, wherein the small devices comprise chip devices.

10. The semiconductor wafer device of claim 9, wherein the small devices are less than 4 mm².

11. The semiconductor wafer device of claim 10, wherein the chip devices attach to small RFID antennas.

12. The semiconductor wafer device of claim 1, wherein the small and large devices are ejected from the wafer device at different times, as the small and large devices are used in different processes.

13. The semiconductor wafer device of claim 12, wherein the large devices are laser cut and ejected first from the wafer device and the small devices are laser cut and ejected second from the wafer device.

14. The semiconductor wafer device of claim 1, further comprising a 3-D stack of devices.

15. The semiconductor wafer device of claim 14, wherein a top device of the 3-D stack of devices comprises a digital processor and a bottom device of the 3-D stack of devices comprises a sensor.

16. A semiconductor wafer device, comprising:
a round wafer with a large surface area and a low cost per unit area;
a plurality of interposer devices manufactured on the wafer; and
a plurality of chip devices manufactured on the wafer; and
wherein the chip devices act as fill in elements for the wafer, as the plurality of interposer devices do not efficiently fill in the wafer; and
wherein the chip devices and the interposer devices are laser cut and ejected from the wafer device at different times.

17. The semiconductor wafer device of claim 16, wherein the interposer devices are greater than 4 mm².

18. The semiconductor wafer device of claim 16, wherein the chip devices are less than 4 mm².

19. The semiconductor wafer device of claim 16, further comprising a 3-D stack of devices manufactured on the wafer comprising a top device and a bottom device, wherein the top device comprises a digital processor and the bottom device comprises a high density coil.

20. A semiconductor wafer device, comprising:
a round wafer with a large surface area;
a plurality of interposer devices and a plurality of chip devices manufactured on the wafer;
wherein the chip devices act as fill in elements for the wafer, as the plurality of interposer devices do not efficiently fill in the wafer; and
a 3-D stack of devices manufactured on the wafer comprising a top device and a bottom device, wherein the top device comprises a digital processor and the bottom device comprises a high density coil.
